(19) United States
(12) Patent Application Publication
(10) Pub. No.: US 2026/0182228 A1
(43) Pub. Date: Jun. 25, 2026

(54) Display Device

(71) Applicant: LG Display Co., Ltd., Seoul (KR)

(72) Inventors: Saehoon Oh, Paju-si (KR); Minwoo Nam, Paju-si (KR)

(21) Appl. No.: 19/376,373

(22) Filed: Oct. 31, 2025

(30) Foreign Application Priority Data
Dec. 20, 2024 (KR) 10-2024-0192474

(51) Int. Cl. H10K 59/80; H10K 59/122

(52) U.S. Cl. CPC H10K 59/8792; H10K 59/122; H10K 59/873

(57) ABSTRACT

A display device includes a first electrode disposed on the substrate. The display device further includes a bank disposed on an edge of the first electrode and includes a first part and a second part that encloses an area in which the first part is disposed. The display device further includes an organic layer disposed in a part of a top surface of the first electrode. The display device further includes a second electrode disposed on the organic layer and the bank. The display device further includes an encapsulation layer disposed on the second electrode. The display device further includes a color filter layer disposed on the encapsulation layer and that overlaps the organic layer and the first part. The display device further includes a black matrix disposed on the encapsulation layer and that overlaps the second part.

### CROSS-REFERENCE TO RELATED APPLICATION

This application claims the priority of Republic of Korea Patent Application No. 10-2024-0192474 filed on Dec. 20, 2024, which is incorporated by reference in its entirety.

### BACKGROUND

### Field

The present disclosure relates to a display device, and more particularly, to a display device which reduces external light reflectance.

### Description of the Related Art

Generally, an organic light emitting display device includes an anode, a cathode, and an organic light emitting layer disposed therebetween. However, the cathode is formed using a metal material having a high reflectance so that the external light is reflected by the metal material to deteriorate reflective visibility and a contrast ratio. Therefore, in order to reduce the reflection by the external light, a polarization plate is disposed below a cover member to absorb the external light. The polarization plate is a film having a predetermined level of light transmittance and absorbs external light and reflected light thereof to suppress the degradation of the contrast ratio.

Recently, as interest in a flexible and slim display device is increased, instead of a thick polarization plate, a display device to which a coated polarization film with a relatively small thickness is applied has been proposed. However, there are problems in that the thickness of the coated polarization film is also large and if the thickness thereof is reduced, a function and a display quality of the polarization film are degraded.

### SUMMARY

An object to be achieved by the present disclosure is to provide a display device having a structure which reduces an external light reflectance in a structure in which a color filter layer is disposed on an encapsulation layer.

An object to be achieved by the present disclosure is to provide a display device which improves a viewing angle characteristic by allowing a color filter layer to overlap a part of the non-emission area.

Objects of the present disclosure are not limited to the above-mentioned objects, and other objects, which are not mentioned above, can be clearly understood by those skilled in the art from the following descriptions.

According to one or more embodiments of the present disclosure, there is provided a display device. The display device includes a substrate including a plurality of sub pixels. The display device further includes a first electrode disposed on the substrate. The display device further includes a bank disposed on an edge of the first electrode and includes a first part and a second part that encloses an area in which the first part is disposed. The display device further includes an organic layer disposed in a part of a top surface of the first electrode. The display device further includes a second electrode disposed on the organic layer and the bank. The display device further includes an encapsulation layer disposed on the second electrode. The display device further includes a color filter layer disposed on the encapsulation layer, and the color filter layer disposed on the organic layer and the first part. The display device further includes a black matrix disposed on the encapsulation layer, and the black matrix disposed on the second part. The entire first part is disposed on the first electrode, the second part is disposed on a part of the first electrode, and a height of the first part is smaller than a height of the second part.

According to one or more embodiments of the present disclosure, there is provided a display device. The display device includes a substrate including an emission area, a first non-emission area that encloses the emission area, and a second non-emission area that encloses the first non-emission area. The display device further includes a first electrode disposed on the substrate. The display device further includes a bank disposed on an edge of the first electrode. The display device further includes an organic layer disposed in a part of a top surface of the first electrode. The display device further includes a second electrode disposed on the organic layer and the bank. The display device further includes an encapsulation layer disposed on the second electrode. The display device further includes a color filter layer disposed on the encapsulation layer, and the color filter layer is disposed in the emission area and the first non-emission area. The display device further includes a black matrix disposed on the encapsulation layer, and the black matrix is disposed in the second non-emission area. The bank includes a first part disposed in the first non-emission area and a second part disposed in the second non-emission area, and a height of the first part is smaller than a height of the second part.

Other detailed matters of embodiments of the present disclosure are included in the detailed description and the drawings.

According to one or more embodiments of the present disclosure, a structure which offsets external light is included in a part of a non-emission area which encloses the emission area so that the external light reflectance is lowered, which enables low-power driving.

According to one or more embodiments of the present disclosure, it is possible to be driven at a voltage lower than that of the display device which includes a polarization plate to reduce power consumption and contribute to the increase in the lifespan and provide excellent luminous efficiency.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic plan view of a display device according to one or more embodiments of the present disclosure.

FIG. 2 is a view schematically illustrating an emission area and a non-emission area included in a display area of a display device according to one or more embodiments of the present disclosure.

FIG. 3 is a cross-sectional view taken along A-B of FIG. 2.

FIG. 4 is a view schematically illustrating a laminated structure for a first non-emission area of FIG. 3.

FIG. 5 is a view schematically illustrating a path of external light which is incident to a first non-emission area of FIG. 3.

FIG. 6 is a graph illustrating an external light reflectance according to a thickness of a first part of a bank in a first non-emission area of a display device according to one or more embodiments of the present disclosure.

FIG. 7 is a table illustrating an external light reflectance for a wavelength of 550 nm of FIG. 6.

FIG. 8 is a graph illustrating an external light reflectance according to a thickness of a second electrode of a light emitting diode in a first non-emission area of a display device according to one or more embodiments of the present disclosure.

FIG. 9 is a table illustrating an external light reflectance for a wavelength of 550 nm of FIG. 8.

FIGS. 10 to 14 are views schematically illustrating a manufacturing method of a display device according to one or more embodiments of the present disclosure.

FIG. 15 is a cross-sectional view illustrating an emission area and a non-emission area included in a display area of a display device according to one or more embodiments of the present disclosure.

### DETAILED DESCRIPTION

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to one or more embodiments of the present disclosure will be described in detail with reference to accompanying drawings.

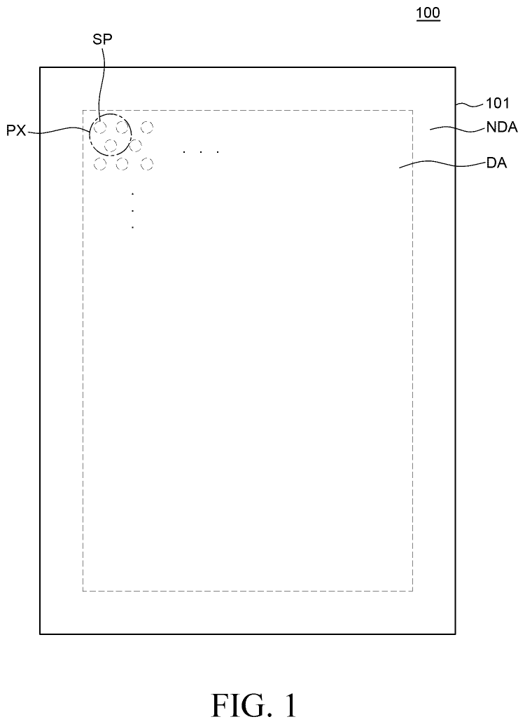

FIG. 1 is a schematic plan view of a display device according to one or more embodiments of the present disclosure.

Referring to FIG. 1, a display device 100 according to one or more embodiments of the present disclosure includes a display panel 101 equipped with a display element which displays images, a driving element which drives the display element, and a signal line which transmits various signals to the display element and the driving element.

The display element may be defined in different manners depending on the type of the display panel 101.

In one or more embodiments of the present disclosure, an example that the display panel 101 is an organic light emitting display panel will be described and at this time, the display element is an organic light emitting diode including an anode electrode, an organic emission layer, and a cathode electrode.

That is, the display device 100 according to one or more embodiments of the present disclosure may be an organic light emitting display device in which the light emitting diode is implemented by an organic light emitting diode (OLED).

As another example, the display device 100 may be an inorganic light emitting display device in which the light emitting diode is implemented by an inorganic material-based light emitting diode.

As still another example, the display device 100 may be a quantum-dot display device in which the light emitting diode is implemented by a quantum dot which is a self-emitting semiconductor crystal.

Further, the display device 100 according to one or more embodiments of the present disclosure may be a flexible organic light emitting display device.

The display panel 101 may be configured to include a substrate, a plurality of insulating films, a transistor layer, and a light emitting diode layer on the substrate.

The display panel 101 may include a plurality of sub pixels SP for displaying images and various signal lines for driving the plurality of sub pixels SP. The signal lines may include a plurality of data lines, a plurality of gate lines, and a plurality of power lines.

A plurality of data lines and a plurality of gate lines disposed in the display panel 101 may intersect each other.

Each of the plurality of data lines may extend in a first direction. Each of the plurality of gate lines may extend in a second direction.

Here, the first direction may be a column direction and the second direction may be a row direction. Alternatively, the first direction may be a row direction and the second direction may be a column direction.

As illustrated in FIG. 1, the display panel 101 includes a display area DA in which an image is displayed and a non-display area NDA in which no image is displayed.

In the display area DA, a plurality of pixels PX, a plurality of sub pixels SP which configures the pixel PX, and a pixel circuit for driving the plurality of sub pixels SP.

Each sub pixel SP may include a transistor located on the transistor layer and a light emitting diode located on the light emitting diode layer.

The sub pixel SP is a minimum unit which configures the display area DA and a display element may be disposed in each of the plurality of sub pixels SP.

The pixel circuit for driving the plurality of sub pixels SP may be configured by a thin film transistor, a storage capacitor, a gate line, and a data line, but is not limited thereto.

The non-display area NDA is bent so as not to be seen from a front surface or blocked by a case (not illustrated) and may also be referred to as a bezel area.

In the non-display area NDA, various lines and circuits for driving the light emitting diode of the display area DA may be disposed.

For example, in the non-display area NDA, a link line which transmits signals to the plurality of sub pixels and circuits of the display area DA, a gate-in-panel (GIP) line, or a driving IC, such as a gate driver IC or a data driver IC, may be disposed, but it is not limited thereto.

For example, in the non-display area NDA, a ground line which is disposed to enclose the display area DA and applies a common voltage to the sub pixel may be included. For example, one or two or more ground lines may be formed. When two or more ground lines are formed, the ground line closer to the display area DA may be referred to as an internal ground line.

Further, even though it is not illustrated, the display device 100 may include a touch sensing unit including a plurality of touch electrodes. In the plurality of touch electrodes, a touch routing line which transmits a touch signal may be disposed.

Further, the display device 100 may further include various additional elements to generate various signals or drive the pixel in the display area DA. The additional elements for driving the pixels may include an inverter circuit, a multiplexer, or an electrostatic discharge (ESD) circuit.

Further, the display device 100 may further include an additional element associated with a function other than a function of driving a pixel PX.

For example, the display device 100 may further include additional elements which provide a touch sensing function, a user authentication function (for example, fingerprint recognition), a multilevel pressure sensing function, or a tactile feedback function. The above-mentioned additional elements may be located in an external circuit which is connected to the non-display area NDA and/or the connecting interface.

Further, the display device 100 may include a display driving circuit for driving the display panel 101 and include a data driving circuit, a gate driving circuit, and a display controller as a display driving circuit.

The data driving circuit is a circuit for driving a plurality of data lines and may output data signals to the plurality of data lines. The gate driving circuit is a circuit for driving a plurality of gate lines and may output gate signals to the plurality of gate lines.

The display controller is a device for controlling the data driving circuit and the gate driving circuit and may control a driving timing for the plurality of data lines and a driving timing for the plurality of gate lines.

The display controller may supply a data driving control signal to the data driving circuit to control the data driving circuit and supply a gate driving control signal to the gate driving circuit to control the gate driving circuit.

The display controller may receive input image data from a host system to supply image data to the data driving circuit based on input image data.

The data driving circuit may supply data signals to the plurality of data lines in response to the driving timing control of the display controller. The data driving circuit may receive digital image data from the display controller and convert the received image data into analog data signals to output the converted data signals to the plurality of data lines.

The gate driving circuit may supply gate signals to the plurality of gate lines in response to the timing control of the display controller. The gate driving circuit is supplied with a first gate voltage corresponding to a turn-on level voltage and a second gate voltage corresponding to a turn-off level voltage together with various gate driving control signals to generate gate signals and may supply the generated gate signals to the plurality of gate lines.

The gate driving circuit supplies a gate signal to the gate line in accordance with a gate driving control signal supplied from the display controller. The gate driving circuit may be disposed at one side or both sides of the display panel 101 in a gate in panel (GIP) manner.

The gate driving circuit sequentially outputs gate signals to the plurality of gate lines under the control of the display controller. The gate driving circuit shifts the gate signal using a shift register to sequentially supply the signals to the gate lines.

The gate signal may include a scan signal and an emission control signal in the display device 100. The scan signal pulse is synchronized with the data voltage to select sub pixels SP of a line in which the data is written. The emission control signal defines an emission time of each of the sub pixels SP.

At least one of the data driving circuit and the gate driving circuit may be disposed in the display area DA of the display panel 101.

For example, at least one of the data driving circuit and the gate driving circuit may be disposed so as not to overlap the sub pixels SP or disposed so as to partially or entirely overlap the sub pixels SP.

The display device 100 may further include a power supply circuit which supplies various powers to the display driving circuit and/or the touch sensing circuit.

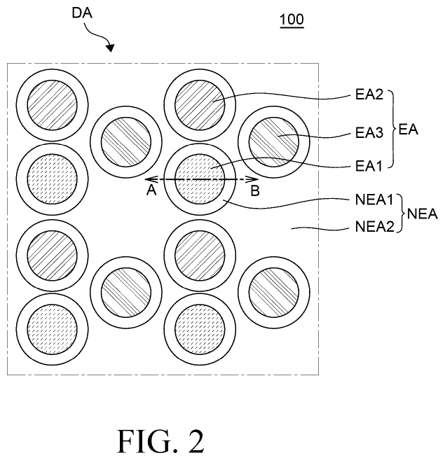

FIG. 2 is a view schematically illustrating an emission area and a non-emission area included in a display area of a display device according to one or more embodiments of the present disclosure.

Referring to FIG. 2, the display area DA of the display device 100 includes a plurality of sub pixels SP.

Each sub pixel SP may include an emission area EA and a non-emission area NEA which encloses the emission area EA.

For example, the display area DA may include a first emission area EA1, a second emission area EA2, and a third emission area EA3 which emit different color lights.

Here, the first emission area EA1 may be an area which emits red light, the second emission area EA2 may be an area which emits green light, and the third emission area EA3 may be an area which emits blue light, but it is not limited thereto.

Further, at least one sub pixel SP, among the plurality of sub pixels SP, may include a first non-emission area NEA1 and a second non-emission area NEA2.

The first non-emission area NEA1 may be disposed so as to enclose one emission area EA and the second non-emission area NEA2 may be disposed so as to enclose the first non-emission area NEA1.

The first non-emission area NEA1 may be an area having a luminance higher than that of the second non-emission area NEA2.

Further, the first non-emission area NEA1 may be an area having a luminance lower than that of the emission area EA. For example, the first non-emission area NEA1 which encloses the first emission area EA1 which emits red light has a luminance of red light lower than that of the first emission area EA1.

In other words, when the display device 100 is in an on-state, the emission area EA, the first non-emission area NEA1, and the second non-emission area NEA2 may have different luminances.

When there is a plurality of sub pixels SP including the first non-emission area NEA1 and the second non-emission area NEA2, a plurality of first non-emission areas NEA1 may be disposed in the display area DA.

The plurality of first non-emission areas NEA1 may be disposed to be spaced apart from each other.

On the plane, the second non-emission area NEA2 may be disposed so as to enclose the plurality of first non-emission areas NEA1.

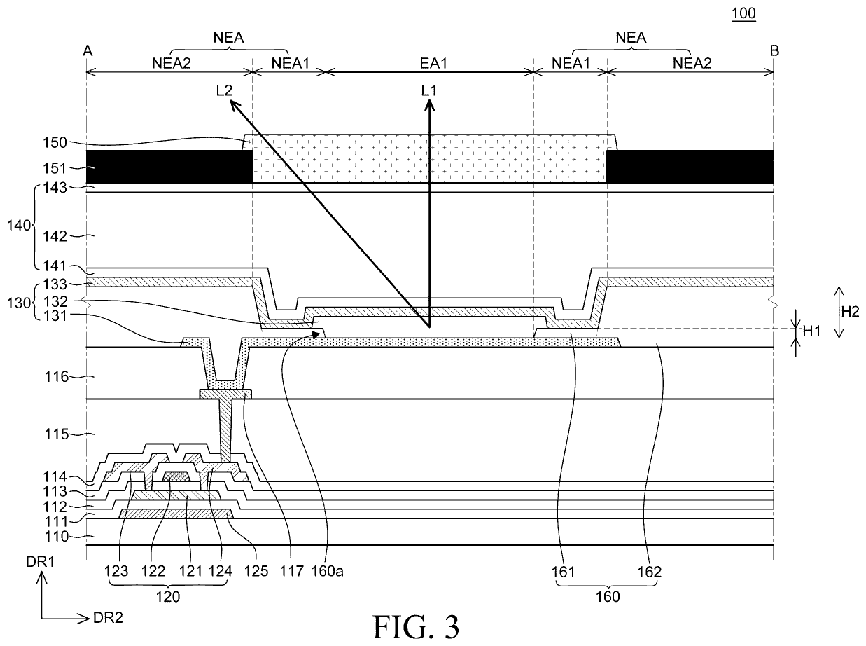

Hereinafter, a structure of a sub pixel SP including one emission area EA, a first non-emission area NEA1, and a second non-emission area NEA2 will be described in more detail with reference to FIGS. 3 to 5.

FIG. 3 is a cross-sectional view taken along A-B of FIG. 2.

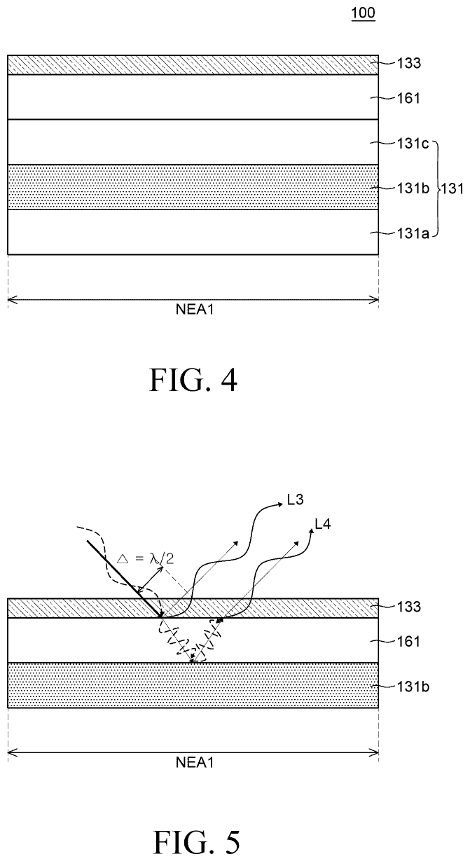

FIG. 4 is a view schematically illustrating a laminated structure for a first non-emission area of FIG. 3.

FIG. 5 is a view schematically illustrating a path of external light which is incident to a first non-emission area of FIG. 3.

Referring to FIGS. 3 to 5, in the display area DA of the display device 100, at least one transistor 120 and at least one light emitting diode 130 may be disposed on the substrate 110.

The transistor 120 may include an active layer 121, a gate electrode 122, a source electrode 124, and a drain electrode 123.

The light emitting diode 130 may include a first electrode 131, an organic layer 132, and a second electrode 133.

Specifically, a light shielding layer 125 may be disposed on the substrate 110.

The light shielding layer 125 is disposed below the active layer 121 of the transistor 120 to serve as a light shield.

The light shielding layer 125 may be a layer of any one of magnesium (Mg), aluminum (Al), nickel (Ni), chrome (Cr), molybdenum (Mo), tungsten (W), gold (Au), titanium (Ti), nickel (Ni), neodymium (Nd), and copper (Cu) or an alloy of two or more of them, or multiple layers thereof, but it is not limited thereto. For example, the light shielding layer 125 may be formed of an organic material.

A buffer layer 111 may be disposed on the light shielding layer 125.

The buffer layer 111 may be formed as a single layer of silicon nitride (SiNx) or silicon oxide (SiOx) which is an inorganic material or multiple layers of silicon nitride (SiNx) and silicon oxide (SiOx), but is not limited thereto.

The active layer 121 of the transistor 120 may be disposed on the buffer layer 111.

The active layer 121 may be formed of an oxide semiconductor or amorphous silicon (a-Si), polycrystalline silicon (poly-Si), or an organic semiconductor.

A gate insulating film 112 may be disposed on the active layer 121.

The gate insulating film 112 may be formed as a single layer of silicon nitride (SiNx) or silicon oxide (SiOx) which is an inorganic material or multiple layers of silicon nitride (SiNx) and silicon oxide (SiOx), but it is not limited thereto.

The gate electrode 122 may be disposed on the gate insulating film 112.

The gate electrode 122 may be a layer of any one of magnesium (Mg), aluminum (Al), nickel (Ni), chrome (Cr), molybdenum (Mo), tungsten (W), gold (Au), titanium (Ti), nickel (Ni), neodymium (Nd), and copper (Cu) or an alloy of two or more of them, or multiple layers thereof, but it is not limited thereto.

The active layer 121 may include a channel region which overlaps the gate electrode 122, a source connection region located at one side of the channel region, and a drain connection region located at the other side of the channel region.

An interlayer insulating layer 113 may be disposed on the substrate 110 on which the gate electrode 122 is disposed.

The interlayer insulating layer 113 may be formed as a single layer of silicon nitride (SiNx) or silicon oxide (SiOx) which is an inorganic material or multiple layers of silicon nitride (SiNx) and silicon oxide (SiOx), but it is not limited thereto.

The source electrode 124 and the drain electrode 123 may be formed on the interlayer insulating layer 113.

The source electrode 124 and the drain electrode 123 may be a layer of any one of magnesium (Mg), aluminum (Al), nickel (Ni), chrome (Cr), molybdenum (Mo), tungsten (W), gold (Au), titanium (Ti), nickel (Ni), neodymium (Nd), and copper (Cu) or an alloy of two or more of them, or multiple layers thereof, but it is not limited thereto.

The source electrode 124 and the drain electrode 123 may be electrically connected to the source connection region and the drain connection region of the active layer 121 through a contact hole provided in the interlayer insulating layer 113.

A protection layer 114 may be disposed on the source electrode 124 and the drain electrode 123.

The protection layer 114 may be formed as a single layer of silicon nitride (SiNx) or silicon oxide (SiOx) which is an inorganic material or multiple layers of silicon nitride (SiNx) and silicon oxide (SiOx), but is not limited thereto.

A first planarization layer 115 may be disposed on the protection layer 114.

The first planarization layer 115 may include an organic material and serve to protect the transistor 120 and planarize a top surface of the substrate 110 on which the transistor 120 is disposed.

A connection electrode 117 may be disposed on the first planarization layer 115.

The connection electrode 117 may serve to electrically connect the transistor 120 and the light emitting diode 130.

The connection electrode 117 may be a layer of any one of magnesium (Mg), aluminum (Al), nickel (Ni), chrome (Cr), molybdenum (Mo), tungsten (W), gold (Au), titanium (Ti), nickel (Ni), neodymium (Nd), and copper (Cu) or an alloy of two or more of them, or multiple layers thereof, but it is not limited thereto.

A second planarization layer 116 may be disposed on the connection electrode 117 and the first planarization layer 115. The second planarization layer 116 may include an organic material.

A light emitting diode 130 including a first electrode 131, an organic layer 132, and a second electrode 133 may be disposed on the second planarization layer 116.

The first electrode 131 may be an anode electrode of the light emitting diode 130 and the second electrode 133 may be a cathode electrode of the light emitting diode 130.

The display device 100 according to one or more embodiments of the present disclosure is a top emission type in which light emitted from the light emitting diode 130 is emitted toward the top of the substrate 110 so that the first electrode 131 may include a reflective electrode layer.

For example, the first electrode 131 is a single layer including a reflective electrode layer, but is not limited thereto. For example, the first electrode 131 may be configured by multiple layers including a reflective electrode layer.

The reflective electrode layer of the first electrode 131 may be formed of silver (Ag), aluminum (Al), gold (Au), molybdenum (Mo), tungsten (W), chrome (Cr), or an alloy thereof.

Further, if the first electrode 131 is formed by multiple layers, a transparent conductive layer disposed below the reflective electrode layer or above and below the reflective electrode layer may be further included.

The transparent conductive layer, for example, may include at least one of indium tin oxide (ITO), indium zinc oxide (IZO), or indium gallium zinc oxide (IGZO), but is not limited thereto.

Specifically, as illustrated in FIG. 4, the first electrode 131 may include a first sub electrode 131a, a second sub electrode 131b disposed on the first sub electrode 131a, and a third sub electrode 131c disposed on the second sub electrode 131b.

Each of the first sub electrode 131a and the third sub electrode 131c may be a transparent conductive layer and the second sub electrode 131b may be a reflective electrode layer.

Referring to FIGS. 3 to 5, the first electrode 131 may be in contact with the source electrode 124 of the transistor 120 through contact holes provided in the protection layer 114, the first planarization layer 115, and the second planarization layer 116.

A bank 160 may be disposed in a part of a top surface of the first electrode 131 and a part of a top surface of the second planarization layer 116.

The bank 160 may include a transparent organic insulating material having a refractive index of 1 or larger. For example, the bank 160 may include polyimide (PI). However, the present disclosure is not limited thereto and the bank 160 may be formed of an organic insulating material, such as a benzocyclobutene resin, an acrylic resin, or an imide resin.

Such a bank 160 may have a dielectric characteristic which has a polarity in an electric field.

In the display device 100 according to one or more embodiments of the present disclosure, the first electrode 131 includes a reflective electrode layer. Accordingly, even though a transparent bank 160 is provided, among external light incident into the display device 100, external light reflection by a plurality of wiring lines or a plurality of electrodes disposed between the first electrode 131 and the substrate 110 may be suppressed.

The bank 160 may include a first part 161 and a second part 162.

The first part 161 of the bank 160 may be a part which overlaps a part of the top surface of the first electrode 131.

At least a part of the second part 162 of the bank 160 may include a part which does not overlap the first electrode 131.

The second part 162 of the bank 160 may be integrally formed with the first part 161 of the bank 160.

An area on the substrate 110 in which the bank 160 is not disposed may be a first emission area EA1 of the sub pixel SP.

An area on the substrate 110 in which the bank 160 is disposed may be a non-emission area NEA of the sub pixel SP.

Specifically, an area in which the first part 161 of the bank 160 is disposed may be a first non-emission area NEA1 and an area in which the second part 162 of the bank 160 is disposed may be a second non-emission area NEA2.

A height H1 of the first part 161 of the bank 160 disposed in the first non-emission area NEA1 may be lower than a height H2 of the second part 162 of the bank 160 disposed in the second non-emission area NEA2. Here, the height H1 of the first part 161 of the bank 160 and the height H2 of the second part 162 of the bank 160 may be the shortest length in the same direction as a direction in which the buffer layer 111 is disposed on the substrate 110.

Accordingly, a boundary of the first non-emission area NEA1 and the second non-emission area NEA2 may have at least one step on the cross section.

The bank 160 may include a bank hole 160a which overlaps a part of the top surface of the first electrode 131.

An area overlapping the bank hole 160a may be a first emission area EA1 of the sub pixel SP and an area which does not overlap the bank hole 160a may be a non-emission area NEA of the sub pixel SP.

The organic layer 132 of the light emitting diode 130 may be disposed on the first electrode 131.

The organic layer 132 may include an area overlapping the bank hole 160a. For example, the organic layer 132 may be disposed only in the bank hole 160a and a part of the organic layer 132 may overlap a part of the first part 161 of the bank 160 due to a process margin of the organic layer 132.

When a part of the organic layer 132 overlaps the first part 161 of the bank 160, the first part 161 of the bank 160 including an organic insulating material is disposed between the first electrode 131 and the organic layer 132. Therefore, the light emitting diode 130 does not emit light in an area in which the organic layer 132 and the first part 161 of the bank 160 overlap.

The organic layer 132 includes an emission layer and may be configured by multiple layers.

The second electrode 133 of the light emitting diode 130 may be disposed on the organic layer 132 and the bank 160.

The second electrode 133 may be formed of a metal alloy. For example, the second electrode 133 may be formed of an alloy of magnesium (Mg) and silver (Ag), but is not limited thereto. It is sufficient if the second electrode 133 included in the display device according to one or more embodiments of the present disclosure is a transflective material.

In the first emission area EA1, the organic layer 132 may be disposed on the first electrode 131 and the second electrode 133 may be disposed on the organic layer 132.

The first non-emission area NEA1 may include an area in which the first part 161 of the bank 160 is disposed on the first electrode 131 and the second electrode 133 is disposed on the first part 161 of the bank 160.

The second non-emission area NEA2 may include a part of an area in which the second part 162 of the bank 160 is disposed on the first electrode 131 and the second electrode 133 is disposed on the second part 162 of the bank 160.

Further, the second non-emission area NEA2 may include an area in which the second part 162 of the bank 160 is disposed on the second planarization layer 116 and the second electrode 133 is disposed on the second part 162 of the bank 160.

The encapsulation layer 140 may be disposed on the second electrode 133.

The encapsulation layer 140 may have a single layer structure or a multi-layered structure. For example, the encapsulation layer 140 may include a first encapsulation layer 141, a second encapsulation layer 142, and a third encapsulation layer 143.

The first encapsulation layer 141 and the third encapsulation layer 143 may be configured by inorganic films and the second encapsulation layer 142 may be configured by an organic film. Among the first encapsulation layer 141, the second encapsulation layer 142, and the third encapsulation layer 143, the second encapsulation layer 142 is the thickest and may serve as a planarization layer.

The first encapsulation layer 141 may be disposed on the second electrode 133 and be disposed to be the most adjacent to the light emitting diode 130.

The first encapsulation layer 141 may be formed along a surface shape of the second electrode 133. Therefore, a surface of the first encapsulation layer 141 may not be flat due to the bank hole 160a of the bank 160.

The first encapsulation layer 141 may be formed of an inorganic insulating material on which low-temperature deposition can be performed. For example, the first encapsulation layer 141 may be configured by silicon nitride (SiNx), silicon oxide (SiOx), silicon oxynitride (SiON), or aluminum oxide (Al₂O₃). The first encapsulation layer 141 is deposited under a low temperature atmosphere so that during the deposition process, the damage of the organic layer 132 of the light emitting diode 130 including an organic material which is vulnerable to the high temperature atmosphere may be suppressed.

The second encapsulation layer 142 may be formed of an organic insulating material, such as acrylic resin, epoxy resin, polyimide, polyethylene, or silicon oxy carbon (SiOC). For example, the second encapsulation layer 142 may be formed by an inkjet method, but is not limited thereto.

Further, even though it is not illustrated in the drawing, in the non-display area NDA, a structure which blocks the flow of the second encapsulation layer 142 which configures the encapsulation layer 140 may be disposed. In order to suppress the collapse of the encapsulation layer 140, one or more structures may be disposed at an end portion of the inclined surface of the encapsulation layer 140 or therearound.

One or more structures may be disposed in a boundary of the display area DA and the non-display area NDA or in the vicinity of the boundary. The structure may be formed of one or more layers formed of at least an organic material, and for example, include a lower layer formed of the same material on the same layer as the second planarization layer 116 and an upper layer formed of the same material on the same layer as the bank 160, but is not limited thereto.

The third encapsulation layer 143 may be formed above the substrate 110 on which the second encapsulation layer 142 is formed so as to cover top surfaces and side surfaces of the second encapsulation layer 142 and the first encapsulation layer 141.

At this time, the third encapsulation layer 143 may minimize, at least reduce, or block the permeation of external moisture or oxygen into the first encapsulation layer 141 and the second encapsulation layer 142. For example, the third encapsulation layer 143 may be configured by an inorganic insulating material, such as silicon nitride (SiNx), silicon oxide (SiOx), silicon oxynitride (SiON), or aluminum oxide (Al₂O₃).

A color filter layer 150 and a black matrix 151 may be disposed on the third encapsulation layer 143.

Even though it is not illustrated in the drawing, a plurality of touch electrodes may be disposed on the third encapsulation layer 143. In this case, the plurality of touch electrodes may be disposed in the non-emission area NEA.

The color filter layer 150 and the black matrix 151 are disposed on the third encapsulation layer 143 to reduce the thickness of the display device 100 and easily adjust the transmittance. Therefore, the external light and reflected light are absorbed without degrading luminous efficiency to improve the display quality.

The color filter layer 150 may serve to convert a wavelength of light emitted from the light emitting diode 130 to a specific wavelength. For example, the first emission area EA1 is an area which emits red light so that light emitted from the light emitting diode 130 may be converted into red light by the color filter layer 150.

Specifically, the color filter layer 150 may be disposed in the first emission area EA1 and the first non-emission area NEA1. However, the present disclosure is not limited thereto and a part of the color filter layer 150 may be disposed in a part of the second non-emission area NEA2 due to the process margin of the color filter layer 150.

The color filter layer 150 disposed on the encapsulation layer 140, the color filter layer 150 disposed on the organic layer 132 and the first part 161.

Specifically, the color filter layer 150 may overlap the first electrode 131, the organic layer 132, and the second electrode 133 of the light emitting diode 130 in the first emission area EA1.

Further, the color filter layer 150 may overlap the first electrode 131 of the light emitting diode 130, the first part 161 of the bank 160, and the second electrode 133 of the light emitting diode 130 in the first non-emission area NEA1.

In the meantime, when viewers watch the display device 100, the viewers watch the display device 100 not only from the front surface of the display device 100, but also from the side surface of the display device 100.

Accordingly, the viewing angle characteristic of the display device 100 needs to be ensured so as not to degrade the quality of the image when the display device is watched not only from the front surface, but also from the side surface.

The display device 100 according to one or more embodiments of the present disclosure may include the color filter layer 150 extending not only to the first emission area EA1, but also to the first non-emission area NEA1 to ensure the viewing angle characteristic.

Specifically, some L1 (hereinafter, referred to as first light) of light emitted from the light emitting diode 130 may be emitted to the front surface of the display device 100.

As the first light L1 is emitted to the front surface of the display device 100, a front luminance characteristic of the display device 100 may be improved.

The other light L2 (hereinafter, referred to as second light) of light emitted from the light emitting diode 130 may be emitted in a direction between a first direction DR1 and a second direction DR2. Here, the first direction DR1 is the same direction as a direction in which a buffer layer 111 is laminated on the substrate 110 and the second direction DR2 is a direction perpendicular to the direction in which the buffer layer 111 is disposed on the substrate 110.

The second light L2 may be emitted to the outside of the display device 100 via the color filter layer 150 disposed in the first non-emission area NEA1. The second light L2 is emitted to the direction between the first direction DR1 and the second direction DR2 to improve the viewing angle characteristic of the display device 100.

When the black matrix 151 is disposed in the first non-emission area NEA1, rather than the color filter layer 150, the second light L2 is absorbed by the black matrix 151 and is not emitted to the outside of the display device 100. Therefore, the viewing angle characteristic of the display device 100 may be degraded.

In the display device 100 according to one or more embodiments of the present disclosure, the color filter layer 150 extends to the first non-emission area NEA1, thereby improving the viewing angle characteristic of the display device 100.

In addition, the display device 100 according to one or more embodiments of the present disclosure does not include a polarization plate, so that it is driven at a lower voltage than a display device which includes a polarization plate to reduce consumed power, contribute to increase of lifespan, and have excellent luminous efficiency.

The black matrix 151 may be disposed in the second non-emission area NEA2.

The black matrix 151 may be disposed between sub pixels SP and serve to suppress mixture of light emitted from different emission areas EA.

Further, the black matrix 151 absorbs external light which is incident to a top emission type display device 100 to lower the reflectance of the display device 100.

In the meantime, the black matrix 151 is not disposed in the first non-emission area NEA1 so that an area in which the black matrix 151 absorbs external light is reduced, which causes a problem in that external light reflectance of the display device 100 is increased.

Specifically, when the black matrix 151 is disposed in the first non-emission area NEA1, there is no external light which is reflected by the second electrode 133 disposed in the first non-emission area NEA1. However, when the black matrix 151 is not disposed in the first non-emission area NEA1, there is a problem in that external light is reflected by the second electrode 133 disposed in the first non-emission area NEA1, which significantly increases external light reflectance.

Therefore, the display device 100 according to one or more embodiments of the present disclosure includes a structure in which the first electrode 131 of the light emitting diode 130, the first part 161 of the bank 160, and the second electrode 133 of the light emitting diode 130 are sequentially laminated in the first non-emission area NEA1. Accordingly, external light which is incident into the display device 100 may not be emitted to the outside of the display device 100 again by destructive interference. Therefore, the external light reflectance of the display device 100 may be lowered and the display device 100 may be driven at a low power.

Some of the external light incident to the display device 100 may be reflected from a boundary of the second electrode 133 having a transflective characteristic and the first part 161 of the transparent bank 160 having a dielectric characteristic. The other light of the external light incident to the display device 100 may be reflected by the second sub electrode 131b of the first electrode 131.

However, in the first non-emission area NEA1 of the display device 100 according to one or more embodiments of the present disclosure, a path difference A of a wavelength of external light L3 (hereinafter, referred to as first external light) reflected from the boundary of the second electrode 133 and the first part 161 of the bank 160 and a wavelength of external light L4 (referred to as second external light) reflected by the second sub electrode 131b which is a reflective electrode layer of the first electrode 131 is 2/2, which causes destructive interference.

In other words, when the path difference of the wavelength of first external light L3 and the wavelength of the second external light L4 is 2/2, the destructive interference occurs so that the first external light L3 and the second external light L4 do not escape out of the display device 100, which lowers the external light reflectance.

For example, if external light is incident to the display device 100, approximately 60% of light is reflected from the boundary of the second electrode 133 and the first part 161 of the bank 160. The remaining 40% of light passes through the first part 161 of the bank 160 to reach the second sub electrode 131b. All the external light which reaches the second sub electrode 131b may be reflected.

When all the external light L3 reflected from the boundary of the second electrode 133 and the first part 161 of the bank 160 and the external light L4 reflected by the second sub electrode 131b are emitted to the outside of the display device 100, the external light reflectance of the display device 100 may be increased.

In the display device 100 according to one or more embodiments of the present disclosure, a path difference of the wavelength of the external light L3 reflected from the boundary of the second electrode 133 and the first part 161 of the bank 160 and the wavelength of the external light L4 reflected by the second sub electrode 131b is 2/2, which causes the destructive interference. Therefore, the external light incident to the display device 100 is not emitted to the outside of the display device 100.

Accordingly, a display device 100 with a low reflective characteristic may be implemented.

In the meantime, in order to make the path difference of the wavelength of the first external light L3 and the wavelength of the second external light L4 λ/2, a thickness of the second electrode 133 having transflective characteristic needs to be adjusted. In addition, the thickness H1 of the first part 161 of the bank 160 which is formed of a transparent organic material may also affect the path difference of the wavelengths of the first external light L3 and the second external light L4.

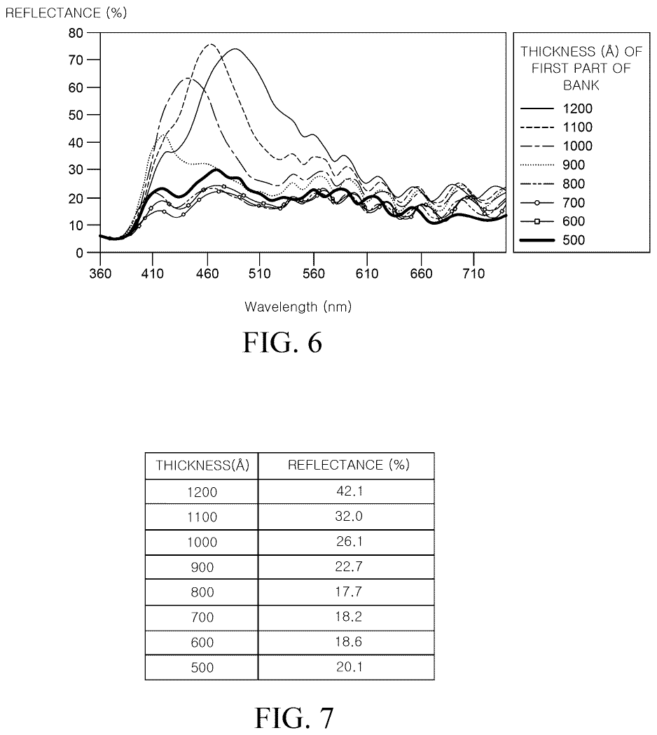

This will be reviewed with reference to FIGS. 6 to 9 as follows.

FIG. 6 is a graph illustrating external light reflectance according to a thickness of a first part of a bank in a first non-emission area of a display device according to one or more embodiments of the present disclosure.

FIG. 7 is a table illustrating an external light reflectance for a wavelength of 550 nm of FIG. 6.

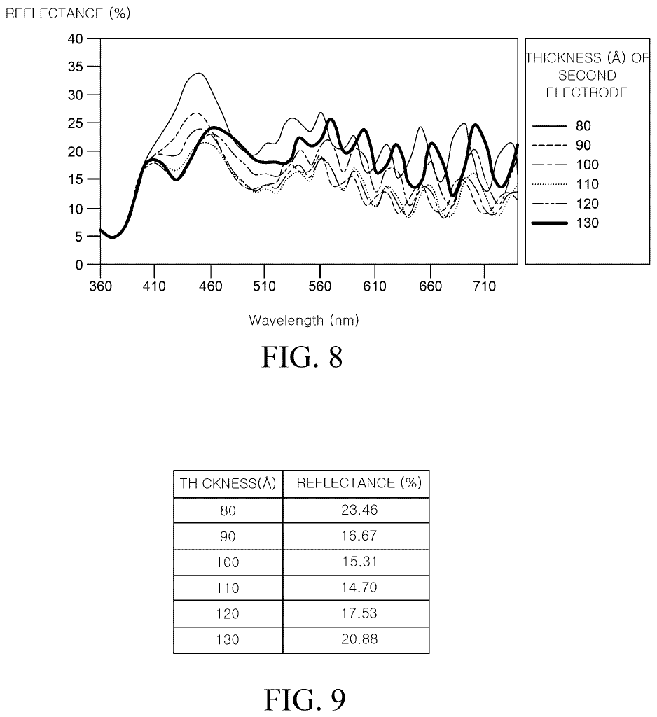

FIG. 8 is a graph illustrating an external light reflectance according to a thickness of a second electrode of a light emitting diode in a first non-emission area of a display device according to one or more embodiments of the present disclosure.

FIG. 9 is a table illustrating an external light reflectance for a wavelength of 550 nm of FIG. 8.

In FIGS. 6 and 7, a thickness of a first sub electrode 131a and a third sub electrode 131c of the first electrode 131 was 70 Å, a thickness of the second sub electrode 131b of the first electrode 131 was 1000 Å, the thickness of the second electrode 133 was fixed to 100 Å, and a thickness H1 of the first part 161 of the bank 160 was changed to measure the reflectance of the external light.

In FIGS. 8 and 9, a thickness of the first sub electrode 131a and the third sub electrode 131c of the first electrode 131 was 70 Å, a thickness of the second sub electrode 131b of the first electrode 131 was 1000 Å, the thickness H1 of the first part 161 of the bank 160 was fixed to 800 Å, and a thickness of the second electrode 133 was changed to measure the reflectance of the external light.

First, referring to FIGS. 6 and 7, it is understood that the reflectance according to the wavelength of external light varies depending on the thickness H1 of the first part 161 of the bank 160.

Specifically, it is understood that with regard to the external light having a wavelength of 550 nm, when the thickness H1 of the first part 161 of the bank 160 is 800 Å, the reflectance of the external light is the lowest.

In other words, with regard to the external light having a wavelength of 550 nm, when the thickness H1 of the first part 161 of the bank 160 is 800 Å, the wavelength of the external light reflected from the boundary of the second electrode 133 of the light emitting diode 130 and the first part 161 of the bank 160 and the wavelength of the external light reflected from the first electrode 131 of the light emitting diode 130 may cause the greatest amount of destructive interference.

Further, when the thickness H1 of the first part 161 of the bank 160 is 600 Å to 800 Å, the reflectance of the external light is formed to be less than 20% so that it is understood that the external light reflectance of the first non-emission area NEA1 is significantly reduced.

Next, referring to FIGS. 8 and 9, it is understood that the reflectance of the external light varies also depending on the thickness of the second electrode 133 of the light emitting diode 130.

Referring to FIGS. 8 and 9, when the thickness of the second electrode 133 is 90 Å to 120 Å with regard to external light having a wavelength of 550 nm, the reflectance of the external light is formed to be less than 20% so that it is understood that the external light reflectance of the first non-emission area NEA1 is significantly reduced.

When the thickness of the second electrode 133 is less than 90 Å, the second electrode 133 has a transmissive characteristic, rather than the transflective characteristic so that the destructive interference of external light reflected from the boundary of the second electrode 133 and the first part 161 of the bank 160 and the external light reflected by the first electrode 131 may be degraded.

Therefore, the thickness of the second electrode 133 may be 90 Å to 120 Å.

The thickness of the second sub electrode 131b of the first electrode 131 may be larger than the thickness H1 of the first part 161 of the bank 160 and the thickness of the second electrode 133. Further, the thickness H1 of the first part 161 of the bank 160 may be larger than the thickness of the second electrode 133.

As described above, in the display device 100 according to one or more embodiments of the present disclosure, in the first non-emission area NEA1, the thickness of the second sub electrode 131b of the first electrode 131, the thickness H1 of the first part 161 of the bank 160, and the thickness of the second electrode 133 are adjusted to improve the external light reflection of the display device 100.

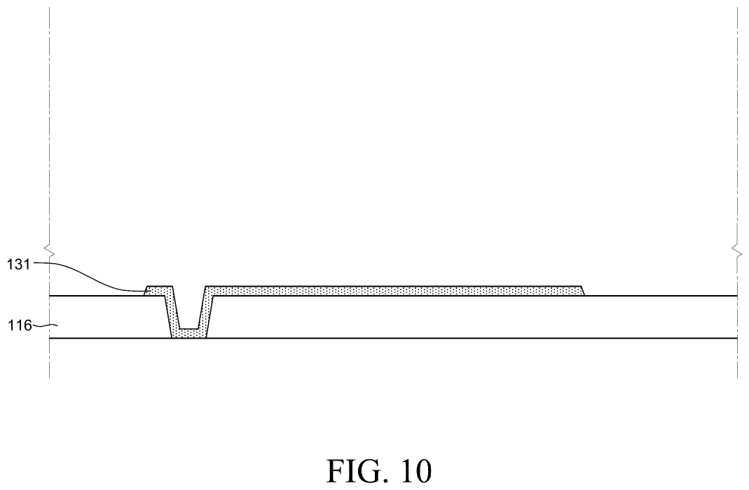

Next, a manufacturing method of a display device according to one or more embodiments of the present disclosure will be briefly reviewed with reference to FIGS. 10 to 14.

FIGS. 10 to 14 are views schematically illustrating a manufacturing method of a display device according to one or more embodiments of the present disclosure.

Referring to FIG. 10, the first electrode 131 of the light emitting diode 130 may be disposed in a part of the second planarization layer 116.

In FIG. 10, a structure in which the first electrode 131 is a single layer is illustrated, but the structure of the first electrode 131 may be a structure illustrated in FIG. 4.

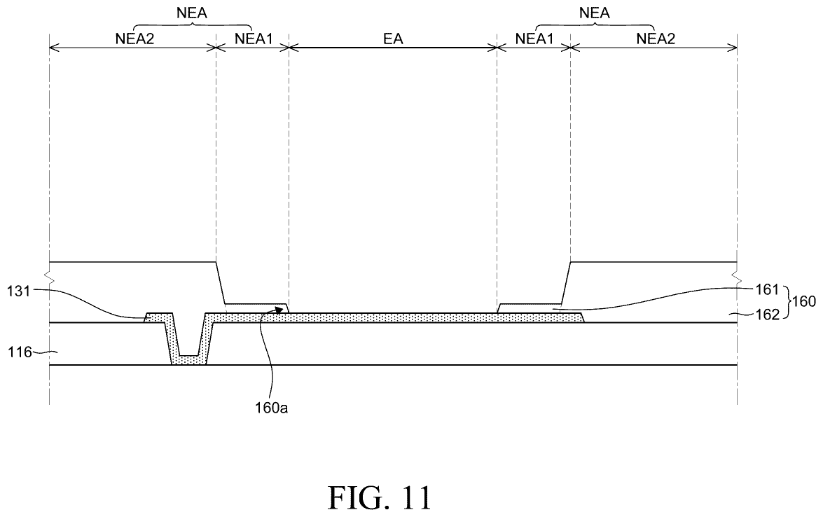

Referring to FIG. 11, a bank 160 may be formed in a part of a top surface of the first electrode 131 and the second planarization layer 116.

Specifically, a bank material used for forming the bank 160 may be disposed on the second planarization layer 116 on which the first electrode 131 is formed.

Thereafter, the bank material may be partially patterned using a halftone mask.

All the bank material disposed in a part of the top surface of the first electrode 131 may be removed.

Further, the bank material which is disposed in a partial area which encloses an area from which all the bank material disposed in a part of the top surface of the first electrode 131 is removed may be partially removed to reduce the height. The area from which the bank material is partially removed to reduce the height of the bank material may overlap a part of the top surface of the first electrode 131.

Further, the bank material disposed in the area which encloses the area from which the bank material is partially removed to reduce the height of the bank material may not be removed. A part of the area from which the bank material is not disposed may overlap a part of the top surface of the first electrode 131 and a top surface of the second planarization layer 116 in which the first electrode 131 is not disposed.

The bank 160 which is formed by the process as described above may include a bank hole 160a, a first part 161, and a second part 162.

The bank hole 160a is a part from which all the bank material is removed.

The first part 161 of the bank 160 may be disposed in a part of the top surface of the first electrode 131 while enclosing the bank hole 160a.

The second part 162 of the bank 160 may be disposed in a part of the top surface of the first electrode 131 and the second planarization layer 116 while enclosing the first part 161.

The bank hole 160a may correspond to the emission area EA, the first part 161 of the bank 160 may correspond to the first non-emission area NEA1, and the second part 162 of the bank 160 may correspond to the second non-emission area NEA2.

As described above, the first part 161 and the second part 162 of the bank 160 are formed using the halftone mask, thereby simplifying the process.

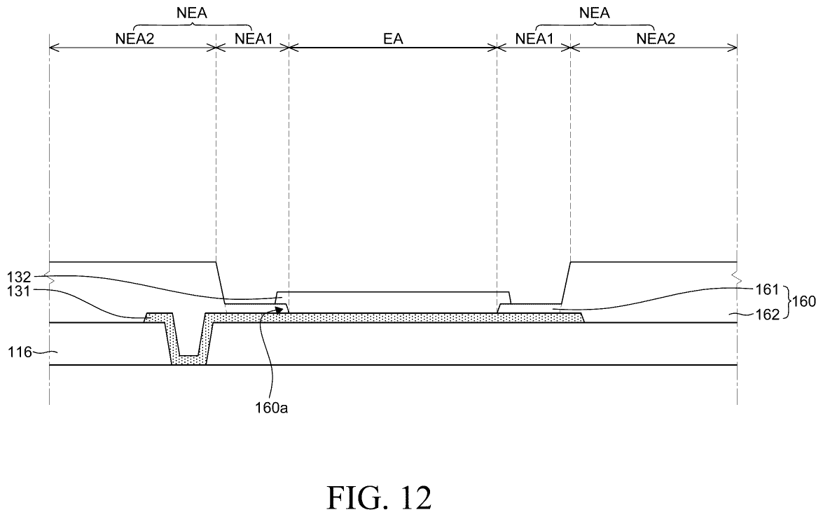

Next, referring to FIG. 12, the organic layer 132 may be formed in a part of the top surface of the first electrode 131.

Specifically, an organic layer material may be disposed on the first electrode 131 and the bank 160.

Next, the organic layer 132 may be formed by a patterning process of removing a part of the organic layer material and remaining the remaining part.

The organic layer 132 may be disposed on the top surface of the first electrode 131 which does not overlap the bank 160.

Further, the organic layer 132 may be disposed in the emission area EA.

In the meantime, during the process of forming the organic layer 132, a part of the organic layer 132 may be disposed in a part of the top surface of the first part 161 of the bank 160 due to the process margin.

However, the structure of the display device 100 according to one or more embodiments of the present disclosure is not limited thereto and the organic layer 132 may be disposed only on the top surface of the first electrode 131 which does not overlap the bank 160.

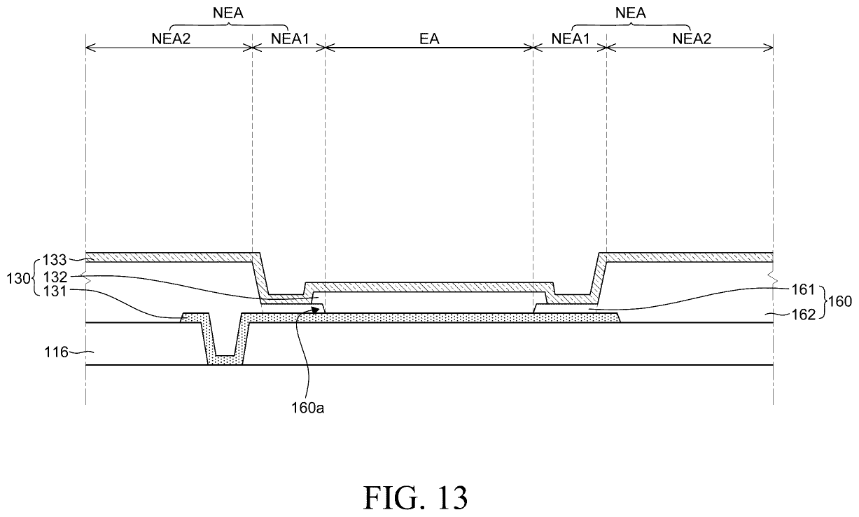

Next, referring to FIG. 13, the second electrode 133 of the light emitting diode 130 may be formed on the organic layer 132 and the bank 160.

The second electrode 133 may be entirely formed in the emission area EA, the first non-emission area NEA1, and the second non-emission area NEA2.

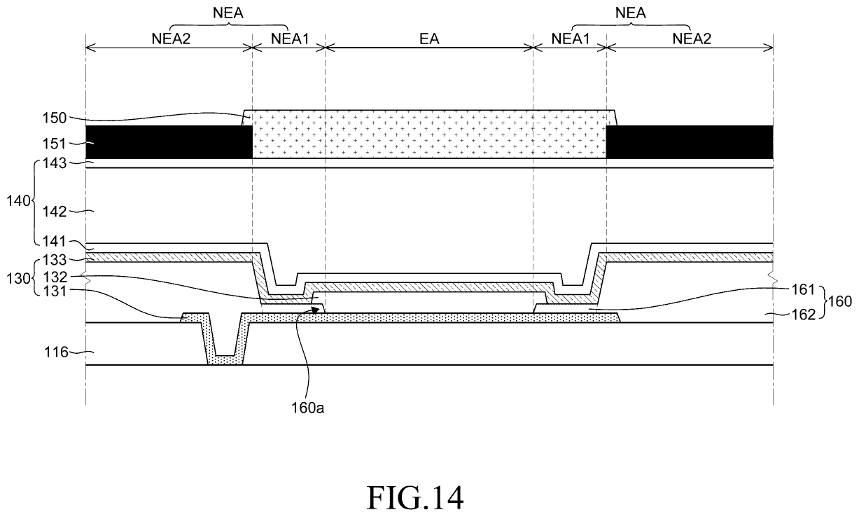

Next, referring to FIG. 14, the encapsulation layer 140 may be disposed on the second electrode 133.

Specifically, the first encapsulation layer 141 may be formed on the second electrode 133, the second encapsulation layer 142 may be formed on the first encapsulation layer 141, and the third encapsulation layer 143 may be disposed on the second encapsulation layer 142.

The black matrix 151 may be formed on the third encapsulation layer 143.

Specifically, a black matrix material may be formed on the third encapsulation layer 143. Next, a part of the black matrix material is removed and the remaining part remains by the patterning process to form the black matrix 151.

The black matrix 151 may disposed on the encapsulation layer 140 and the second part 162 of the bank 160.

Specifically, the black matrix 151 may overlap the second part 162 of the bank 160. Further, the black matrix 151 may be disposed in the second non-emission area NEA2.

Next, a color filter layer material may be formed on the black matrix 151 and the third encapsulation layer 143.

Next, a part of the color filter layer material is removed and the remaining part remains by the patterning process to form the color filter layer 150.

The color filter layer 150 may be disposed in the emission area EA and the first non-emission area NEA1.

In the meantime, during the process of forming the color filter layer 150, a part of the color filter layer 150 may also be disposed in a part of a top surface of the black matrix 151 due to the process margin.

However, the structure of the display device 100 according to one or more embodiments of the present disclosure is not limited thereto and the color filter layer 150 may be disposed only on the top surface of the third encapsulation layer 143 which does not overlap the black matrix 151.

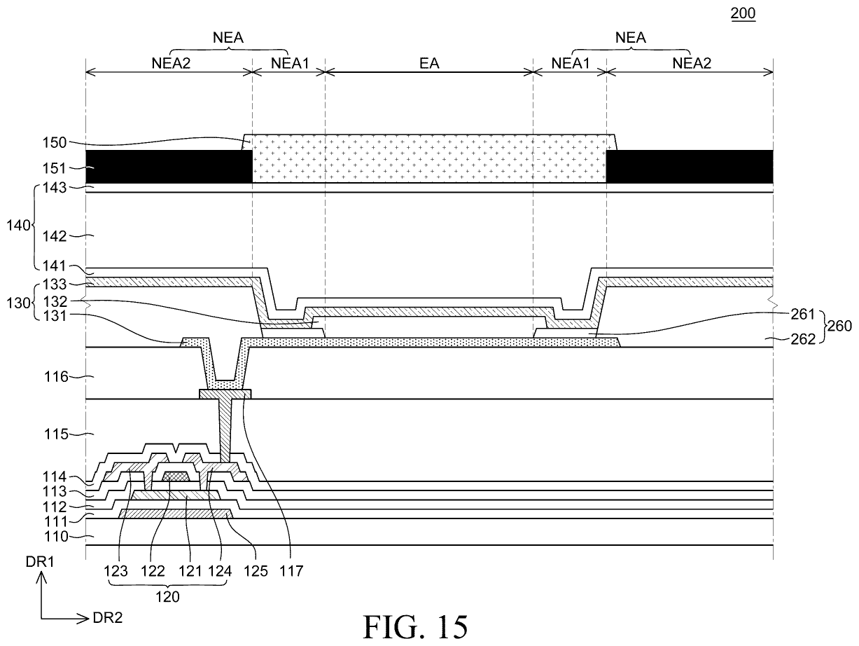

FIG. 15 is a cross-sectional view illustrating an emission area and a non-emission area included in a display area of a display device according to one or more embodiments of the present disclosure.

The only difference between a display device 200 of FIG. 15 and the display device 100 of FIG. 3 is a structure of a bank 260, but the other components are substantially the same, so that a redundant description will be omitted.

Referring to FIG. 15, a bank 260 may be disposed in a part of a top surface of the first electrode 131 and a part of a top surface of the second planarization layer 116 of the display device 200.

The bank 260 may include a first part 261 and a second part 262.

The first part 261 of the bank 260 may be a part which overlaps a part of the top surface of the first electrode 131.

The first part 261 of the bank 260 may be disposed in the first non-emission area NEA1.

The second part 262 of the bank 260 may overlap a part of the top surface of the first electrode 131 and be disposed in an area in which the first part 261 of the bank 260 is not disposed.

The second part 262 of the bank 260 may be disposed in the second non-emission area NEA2.

The first part 261 and the second part 262 of the bank 260 may include different materials.

The first part 261 of the bank 260 may include a transparent inorganic insulating material having a refractive index of 1 or higher. For example, the first part 261 of the bank 260 may include any one of silicon nitride (SiNx) or silicon oxide (SiOx). The first part 261 of the bank 260 may have a dielectric characteristic which has a polarity in the electric field.

The thickness of the first part 261 of the bank 260 may be 600 Å to 800 Å.

The thickness of the second electrode 133 disposed on the first part 261 of the bank 260 may be 90 Å to 120 Å.

The thickness of the first part 261 of the bank 260 and the thickness of the second electrode 133 may determine a reflectance of external light incident to the display device 200.

If external light is incident to the display device 200, approximately 60% of light is reflected from the boundary of the second electrode 133 and the first part 261 of the bank 260. The remaining 40% of light passes through the first part 261 of the bank 260 to reach the second sub electrode 131b. All the external light which reaches the second sub electrode 131b may be reflected.

When all the external light reflected from the boundary of the second electrode 133 and the first part 261 of the bank 260 and the external light reflected by the second sub electrode 131b are emitted to the outside of the display device 200, the external light reflectance of the display device 200 may be increased.

However, the thickness of the first part 261 of the bank 260 may be 600 Å to 800 Å and the thickness of the second electrode 133 may be 90 Å to 120 Å so that the path difference of the wavelengths of the external light reflected from the boundary of the second electrode 133 and the first part 261 of the bank 260 and the external light reflected from the second sub electrode 131b is 2/2, which causes the destructive interference.

The second part 262 of the bank 260 may include an organic insulating material. For example, the second part 262 of the bank 260 may include a benzocyclobutene resin, an acrylic resin, or a polyimide (PI), or imide resin, but is not limited thereto.

The first part 261 and the second part 262 of the bank 260 may be formed by different processes.

For example, after forming the first electrode 131, an inorganic insulating material layer may be formed to form the first part 261 of the bank 260 on the first electrode 131 and the second planarization layer 116.

Next, the inorganic insulating material layer remains only in a part of the top surface of the first electrode 131 and the inorganic insulating material layer disposed in the remaining area is removed by the patterning process to form the first part 261 of the bank 260.

Next, an organic insulating material layer for forming the second part 262 of the bank 260 may be formed on the first electrode 131, the first part 261 of the bank 260, and the second planarization layer 116.

Next, the organic insulating material layer remains only in the other part of the top surface of the first electrode 131 and on the second planarization layer 116 and the organic insulating material layer disposed in the remaining area is removed by the patterning process to form the second part 262 of the bank 260.

Accordingly, there may be a boundary between the first part 261 of the bank 260 and the second part 262 of the bank 260.

However, in the first non-emission area NEA1 of the display device 200 according to one or more embodiments of the present disclosure, a path difference A of a wavelength of external light reflected from the boundary of the second electrode 133 and the first part 261 of the bank 260 and a wavelength of external light reflected by the second sub electrode 131b which is a reflective electrode layer of the first electrode 131 is 2/2, which causes destructive interference.

In other words, in the display device 200 according to one or more embodiments of the present disclosure, a path difference of the wavelength of the external light reflected from the boundary of the second electrode 133 and the first part 261 of the bank 260 and the wavelength of the external light reflected by the second sub electrode 131b is 2/2, which causes the destructive interference. Therefore, the external light incident to the display device 200 is not emitted to the outside of the display device 200 so that the external light reflectance of the display device 200 may be significantly lowered.

Accordingly, the display device 200 with a low reflective characteristic may be implemented.

According to one or more embodiments of the present disclosure, there is provided a display device. The display device includes a substrate including a plurality of sub pixels. The display device further includes a first electrode disposed on the substrate. The display device further includes a bank disposed on an edge of the first electrode and includes a first part and a second part which encloses an area in which the first part is disposed. The display device further includes an organic layer disposed in a part of a top surface of the first electrode. The display device further includes a second electrode disposed on the organic layer and the bank. The display device further includes an encapsulation layer disposed on the second electrode. The display device further includes a color filter layer disposed on the encapsulation layer, and the color filter disposed on the organic layer and the first part. The display device further includes a black matrix disposed on the encapsulation layer, and the black matrix disposed on the second part. The entire first part is disposed on the first electrode, the second part is disposed on a part of the first electrode, and a height of the first part is smaller than a height of the second part.

The first part may be integrated with the second part.

The first part and the second part may include a transparent organic insulating material.

The first part and the second part may include different materials.

The first part may include any one of silicon nitride (SiNx) or silicon oxide (SiOx) and the second part may include an organic insulating material.

At least one sub pixel may include an emission area, a first non-emission area which encloses the emission area, and a second non-emission area which encloses the first non-emission area.

The first part may be disposed in the first non-emission area and the second part may be disposed in the second non-emission area.

In the first non-emission area, the first part may be disposed on the first electrode and the second electrode may be disposed on the first part.

At least one step may be disposed between the first non-emission area and the second non-emission area.

The color filter layer may be disposed in the emission area and the first non-emission area.

The first electrode may include a reflective electrode layer and the second electrode includes a metal alloy.

A thickness of the first part may be 600 Å to 800 Å.

A thickness of the second electrode may be 90 Å to 120 Å.

The first electrode may further include a reflective electrode layer and a thickness of the reflective electrode layer may be larger than a thickness of the first part and a thickness of the second electrode, and the thickness of the first part may be larger than the thickness of the second electrode.

According to one or more embodiments of the present disclosure, there is provided a display device. The display device includes a substrate including an emission area, a first non-emission area that encloses the emission area, and a second non-emission area that encloses the first non-emission area. The display device further includes a first electrode disposed on the substrate. The display device further includes a bank disposed on an edge of the first electrode. The display device further includes an organic layer disposed in a part of a top surface of the first electrode. The display device further includes a second electrode disposed on the organic layer and the bank. The display device further includes an encapsulation layer disposed on the second electrode. The display device further includes a color filter layer disposed on the encapsulation layer, and the color filter layer is disposed in the emission area and the first non-emission area.

The display device further includes a black matrix disposed on the encapsulation layer, and the black matrix is disposed in the second non-emission area. The bank includes a first part disposed in the first non-emission area and a second part disposed in the second non-emission area and a height of the first part is smaller than a height of the second part.

In the first non-emission area, the color filter layer may overlap the first electrode, the first part, and the second electrode.

The first part may be integrated with the second part.

The first part may include any one of silicon nitride (SiNx) or silicon oxide (SiOx) and the second part may include an organic insulating material.

The first electrode may further include a reflective electrode layer, a thickness of the reflective electrode layer may be larger than a thickness of the first part and a thickness of the second electrode, and the thickness of the first part may be larger than the thickness of the second electrode.

The entire first part may overlap the first electrode and the second part may overlap a part of the first electrode.

Although embodiments of the present disclosure have been described in detail with reference to the accompanying drawings, the present disclosure is not limited thereto and may be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate including a plurality of sub pixels;
a first electrode disposed on the substrate;
a bank disposed on an edge of the first electrode, the bank including a first part and a second part that encloses an area in which the first part is disposed;
an organic layer disposed in a part of a top surface of the first electrode;
a second electrode disposed on the organic layer and the bank;
an encapsulation layer disposed on the second electrode;
a color filter layer disposed on the encapsulation layer, the organic layer and the first part; and
a black matrix disposed on the encapsulation layer and the second part,
wherein the entire first part is disposed on the first electrode, the second part is disposed on a part of the first electrode, and a height of the first part is smaller than a height of the second part.

2. The display device according to claim 1, wherein the first part is integrated with the second part.

3. The display device according to claim 1, wherein the first part and the second part include a transparent organic insulating material.

4. The display device according to claim 1, wherein the first part and the second part include different materials.

5. The display device according to claim 4, wherein the first part includes silicon nitride (SiNx) or silicon oxide (SiOx), and the second part includes an organic insulating material.

6. The display device according to claim 1, wherein at least one sub pixel of the plurality of sub pixels includes an emission area, a first non-emission area that encloses the emission area, and a second non-emission area that encloses the first non-emission area.

7. The display device according to claim 6, wherein the first part is disposed in the first non-emission area and the second part is disposed in the second non-emission area.

8. The display device according to claim 6, wherein in the first non-emission area, the first part is disposed on the first electrode and the second electrode is disposed on the first part.

9. The display device according to claim 6, wherein at least one step is disposed between the first non-emission area and the second non-emission area.

10. The display device according to claim 6, wherein the color filter layer is disposed in the emission area and the first non-emission area.

11. The display device according to claim 1, wherein the first electrode includes a reflective electrode layer and the second electrode includes a metal alloy.

12. The display device according to claim 1, wherein a thickness of the first part is 600 Å to 800 Å.

13. The display device according to claim 1, wherein a thickness of the second electrode is 90 Å to 120 Å.

14. The display device according to claim 1, wherein the first electrode further includes a reflective electrode layer, a thickness of the reflective electrode layer is larger than a thickness of the first part and a thickness of the second electrode, and the thickness of the first part is larger than the thickness of the second electrode.

15. A display device, comprising:
a substrate including an emission area, a first non-emission area that encloses the emission area, and a second non-emission area that encloses the first non-emission area;
a first electrode disposed on the substrate;
a bank disposed on an edge of the first electrode;
an organic layer disposed in a part of a top surface of the first electrode;
a second electrode disposed on the organic layer and the bank;
an encapsulation layer disposed on the second electrode;
a color filter layer disposed on the encapsulation layer, the color filter layer disposed in the emission area and the first non-emission area; and
a black matrix disposed on the encapsulation layer, the black matrix disposed in the second non-emission area,
wherein the bank includes a first part disposed in the first non-emission area and a second part disposed in the second non-emission area, and a height of the first part is smaller than a height of the second part.

16. The display device according to claim 15, wherein in the first non-emission area, the color filter layer overlaps the first electrode, the first part, and the second electrode.

17. The display device according to claim 15, wherein the first part is integrated with the second part.

18. The display device according to claim 15, wherein the first part includes silicon nitride (SiNx) or silicon oxide (SiOx), and the second part includes an organic insulating material.

19. The display device according to claim 15, wherein the first electrode further includes a reflective electrode layer, a thickness of the reflective electrode layer is larger than a thickness of the first part and a thickness of the second electrode, and the thickness of the first part is larger than the thickness of the second electrode.

20. The display device according to claim 15, wherein the entire first part overlaps the first electrode, and the second part overlaps a part of the first electrode.
